(19) United States
(12) Patent Application Publication
(10) Pub. No.: US 2015/0015078 A1
(43) Pub. Date: Jan. 15, 2015

(54) Cable and compensation method for transmitting high speed signal and delivering power

(71) Applicant: Ook Kim, Seoul (KR)

(72) Inventor: Ook Kim, Seoul (KR)

(73) Assignee: SMARTPHY INC., Seoul (KR)

(21) Appl. No.: 14/376,151

(22) PCT Filed: Mar. 27, 2012
(86) PCT No.: PCT/KR2012/002207

§ 371 Date: Aug. 1, 2014

(51) Int. Cl. G05F 5/00; H03H 17/02

(52) U.S. Cl. CPC G05F 5/00; H03H 17/0248
USPC 307/103

(57) ABSTRACT

The present specification provides a cable and a compensation method for transmitting a high speed signal and delivering power. The cable according to one embodiment disclosed in the present specification interconnects a first device and a second device, the cable comprising: a power line for transmitting power from the first device to the second device; and a voltage restorer for restoring voltage loss of the power receiving side of the second device generated based on the voltage drop relevant to the power line.

### CROSS-REFERENCE TO RELATED APPLICATIONS

This application is a U.S. national stage application under 35 U.S.C. §371 (c) of PCT Application No. PCT/KR2012/002207, entitled “CABLE AND COMPENSATION METHOD FOR TRANSMITTING HIGH SPEED SIGNAL AND DELIVERING POWER,” filed on Mar. 27, 2012, the disclosure of which is incorporated by reference herein in its entirety.

### TECHNICAL FIELD

This disclosure relates to a cable and a compensating method for high-speed signal transmission and power transfer.

### DISCUSSION OF RELATED ART

A recent increase in demand for electronics having higher resolution and definition has been drastically changing electronics industry. In particular, as display panels such as liquid crystal displays (LCDs), plasma display panels (PDPs), and high-definition televisions (HDTVs) develop, the interface for transmitting high-volume image data plays a critical role.

Interface standards have been created and used in order to apply interfaces to various display panels. The interfaces are classified into external interfaces for connecting display panels with peripherals such as driving devices and internal interfaces for connecting the internal components in a display panel with each other.

A typical internal interface is Low Voltage Differential Signaling (hereinafter, “LVDS”). LVDS is a technique that enables a user to dispose analog and digital signal processing blocks in a separate board, which is a scaler board, so as to transmit data digitalized by an analog-digital (A/D) converter by way of a cable. Here, the term “LV (Low Voltage),” i.e., being a low voltage, means that LVDS adopts 3.3V or 1.5V instead of a standard voltage, 5V. LVDS may use fewer electrical wires in the mother board and display panel and is thus widely used in laptop computers.

As a typical external interface standard, Digital Video/Visual Interactive (hereinafter, “DVI”) is used. DVI is a motion picture technique that may store an image as digital data and reproduce it through a computer monitor.

DVI is a scheme in which a PC sends out an image not in analog but in digital and adopts TMDS coding that converts 8-bit data into 10 bits in order to reduce electromagnetic interference (EMI) and to perform edge tracking. HDMI is an interface obtained by enhancing DVI to have a simplified pin connection and shrunken size and adding digital audio to expand it to consumer electronics such as HDTVs. HDMI has been broadly adopted in cable receivers, Blu-ray players, and most of HDTVs that process high-definition videos. In particular, HDTVs having several video inputs in use typically embed a number of HDMI ports.

In contrast, PCs are further growing up in view of resolution and happened to need technology to support a higher resolution than that of existing HDMI. To meet such need, a high-speed interface, Display Port, has been proposed to meet such requirement. This standard may allow for transmission of 2.7 Gbps×4=10.8 Gbps at the speed of 10 bits at version 1.1a and 21.6 Gbps at version 1.2. This standard provides for signal transmission at higher speed as compared with HDMI thanks to use of AC coupling and pre-emphasis and started to be used as an interface for a high-definition display.

Display Port (DP) is a new digital display interface standard that has been introduced by the Video Electronics Standard Association (VESA) and is a technique that integrates an internal interface and an external interface that typically remain separated from each other. Display Port (DP) enlarges the data bandwidth by combining the two interfaces so that three 1080p streams may be simultaneously transferred in a bandwidth of 10.8 Gbps that is two times or more of the bandwidth offered by DVI, thus enabling transmission of high-quality image signals.

Further, Mobile High-Definition Link (MHL) has been recently introduced as an interface to transmit and receive high-quality images through portable terminals.

MHL is a standard for portable audio/video interfaces, which enables a mobile terminal or other portable electronic device (for example, portable consumer electronics (CEs)) to be directly connected to HDTVs (High-Definition Televisions) or other display apparatuses.

The MHL standard may allow for transmission of 1080p high-definition (HD) video and digital audio signals via a single cable having a low pin count.

Further, MHL may also provide for transmission of power for recharging connected devices along with transmission of the video and audio signals.

The portable interface industry has come to require a technique to transfer power for recharging connected portable devices or apparatuses in addition to high-speed transmission of data such as MHL.

However, as the distance between a transmitting device and a receiving device increases, the length of the cable increases, and in such case, signals transmitted may suffer from attenuation and drop in the transferred voltage due to the signal transfer characteristics of the cable and voltage drop in the cable. Accordingly, increasing the length of the cable may be restricted.

### SUMMARY

### Objects

A technical object of this disclosure is to provide a cable and compensating method for high-speed transmission of signals and power. In particular, according to the cable and compensating method as disclosed herein, a voltage drop component corresponding to a power line included in the cable may be compensated, thus allowing for stable power supply through the cable.

### Solutions

To achieve the above objects, according to the present disclosure, a cable connecting a first device and a second device with each other may comprise: a power line transferring power from the first device to the second device; and a voltage compensator compensating for a power receiving side voltage loss of the second device that is caused due to a voltage drop corresponding to the power line.

As an example relating to the present disclosure, the voltage compensator may include a DC-DC (DC to DC) converter or a boost converter.

As an example relating to the present disclosure, the voltage compensator may compensate for the power receiving side voltage loss based on at least one of a line current flowing through the power line and a power receiving side voltage of the second device.

As an example relating to the present disclosure, the cable may further comprise a current detector detecting a line current flowing through the power line.

As an example relating to the present disclosure, the voltage compensator may compensate for the power receiving side voltage loss based on the detected line current and a line resistance determined depending on a length of the power line.

As an example relating to the present disclosure, the voltage compensator may detect a voltage drop by multiplying the detected line current with the line resistance and adjust an output voltage of the voltage compensator to be the same as a voltage obtained by adding the detected voltage drop to an input voltage of the voltage compensator to thus compensate for the power receiving side voltage loss.

As an example relating to the present disclosure, the voltage compensator may further include a resistor corresponding to the line resistance, and the voltage drop may be a voltage that is generated between both ends of the resistor based on the line current flowing through the resistor.

As an example relating to the present disclosure, the cable may further comprise a memory storing the line resistance.

As an example relating to the present disclosure, the memory may be an OTP (One Time Programmable Memory).

As an example relating to the present disclosure, the memory may store the line resistance according to a length of the power line in the form of a table.

As an example relating to the present disclosure, the voltage compensator may detect a voltage drop by multiplying the detected line current with the line resistance, detect a reference voltage by adding the detected voltage drop to a target voltage, and adjust an output voltage of the voltage compensator to be the same as the reference voltage to thus compensate for the power receiving side voltage loss.

As an example relating to the present disclosure, the target voltage may be a power receiving side voltage of the second device that is to be obtained through voltage compensation by the voltage compensator.

As an example relating to the present disclosure, the voltage compensator may be disposed at a power transmitting side of the first device, a power receiving side of the second device, or a middle position of the power line.

As an example relating to the present disclosure, the cable may further comprise: a data line transferring a data signal from the second device to the first device; and a signal compensator compensating for a loss of the data signal that is caused due to a signal transfer characteristic of the data line.

As an example relating to the present disclosure, the signal compensator may include a boosting amplifier or a DFE (Decision Feedback Equalization).

As an example relating to the present disclosure, the signal compensator may be disposed at a data receiving side of the first device, a data transmitting side of the second device, or a middle position of the data line.

As an example relating to the present disclosure, the voltage compensator may obtain information on a voltage drop corresponding to the power line from the signal compensator and compensate for the power receiving side voltage loss based on the obtained information on the voltage drop.

As an example relating to the present disclosure, the data signal may be a differential data signal.

To achieve the above objects, according to the present disclosure, a compensation method of a cable may comprise the steps of: transferring power from a first device to a second device through a power line; detecting a line current flowing through the power line; and compensating for a power receiving side voltage loss of the second device based on the detected line current and a line resistance determined depending on a length of the power line.

As an example relating to the present disclosure, the step of compensating for the power receiving side voltage loss may comprise the steps of: detecting a voltage drop by multiplying the detected line current with the line resistance; detecting a reference voltage by adding the detected voltage drop to a target voltage; and adjusting a power transmitting side voltage of the first device to be the same as the reference voltage to compensate for the power receiving side voltage loss.

As an example relating to the present disclosure, the method may further comprise the steps: transferring a data signal from the second device to the first device through a data line; and compensating for a loss of the data signal that is caused due to a signal transfer characteristic of the data line.

### Effects

According to an embodiment of this disclosure, a cable and compensating method for high-speed transmission of signals and power are provided.

The cable and compensating method disclosed herein may compensate for a voltage drop component corresponding to a power line included in the cable, thus allowing for stable and efficient power transmission through the cable.

### BRIEF DESCRIPTION OF THE DRAWINGS

FIG. 1 is a block diagram illustrating a configuration of a cable according to embodiments disclosed herein.

FIG. 2 is a flowchart illustrating a compensation method of a cable according to embodiments disclosed herein.

FIG. 3 is a view illustrating a method of disposing a voltage compensator according to a first embodiment disclosed herein.

FIG. 4 is a flowchart illustrating a compensation method of a cable according to a second embodiment disclosed herein.

FIG. 5 is a flowchart illustrating a method of compensating for a voltage based on a detected line current and a line resistance according to the second embodiment disclosed herein.

FIG. 6 is a flowchart illustrating a method of compensating for a voltage based on a detected line current and a line resistance according to another second embodiment disclosed herein.

FIG. 7 is a view illustrating an example structure of a voltage compensator according to the second embodiment disclosed herein.

FIG. 8 is a view illustrating an example structure of a voltage compensator according to still another second embodiment disclosed herein.

FIG. 9 is a flowchart illustrating a compensation method of a cable according to a third embodiment disclosed herein.

FIG. 10 is a view illustrating an example signal compensator according to the third embodiment disclosed herein.

FIG. 11a to 11c are views illustrating example arrangements of a voltage compensator and a signal compensator according to the third embodiment disclosed herein.

FIG. 12 is a view illustrating example waveforms of signals from an MHL system.

FIG. 13 is a concept view illustrating a method of compensate for a signal in an MHL system.

### DETAILED DESCRIPTION OF EMBODIMENTS

The techniques disclosed herein may apply to a cable for high-speed transmission of signals and power and a method of compensating for losses of data signals or power by the cable. However, the techniques disclosed herein are not limited thereto, and may also apply to cables and connecting means connecting all of the devices to which the technical spirit of the techniques are applicable, and methods of compensating for losses of data or power delivered by the cables or connecting means.

For example, the techniques disclosed herein may be applicable to various terminals, such as smartphones, portable terminals, mobile terminals, personal digital assistants (PDAs), portable multimedia player (PMP) terminals, laptop computers, Wibro terminals, Internet protocol television (IPTV) terminals, terminals for digital broadcast, telematics terminals, navigation terminals, audio video navigation (AVN) terminals, televisions, DVD players, set-top boxes, mobile phones, tablet PCs, digital cameras, 3D televisions, A/V (Audio/Video) systems, home theater systems, information providing centers, and call centers.

Further, the cables disclosed herein may be applicable to various wired communication-related protocol or interface technical fields, such as, e.g., USB (Universal Serial Bus) ports, HDMI (High-Definition Multi-media Interface) ports, DPs (Display Ports), MHLs (Mobile High-Definition Links), wired/wireless headset ports, external recharger ports, wired/wireless data ports, memory card ports, ports for connecting identifying module-equipped devices, audio I/O (Input/Output) ports, video V/O (Input/Output) ports, and earphone ports.

The technical terms used herein are given only for the purposes of describing specific embodiments, and should not be construed as intended to limit the technical spirit disclosed herein. Further, the technical terms used herein should, unless defined otherwise, be interpreted as commonly understood by one of ordinary skill in the art to which the techniques disclosed herein pertain, but neither overly comprehensively nor narrowly. Further, the technical terms used herein, when determined to be wrong ones that do not precisely represent the technical spirit disclosed herein, should be instead replaced as correctly understood by one of ordinary skill in the art. Further, the common terms used herein should be construed in the context or as defined in the dictionary, but not to be too narrow.

Further, the singular form used herein, unless clearly stated otherwise, includes the plural form. As used herein, the terms “comprise” and “include” should not be construed to essentially include all of several components or steps disclosed in the specification, but it should be rather interpreted that some of the components or steps may not be included or additional components or steps may be included.

Further, as used herein, the terms “first” and “second” may be used to describe various components but the components are not limited to the terms. The terms are used only for the purpose of distinguishing one component from another. For example, the first component may be denoted the second component, and vice versa, without departing from the scope of the present invention.

Hereinafter, embodiments disclosed herein are described in detail with reference to the accompanying drawings, wherein the same reference numerals refer to the same or similar components of which the repetitive description will be skipped.

Further, when determined to render the subject matter of the present disclosure unclear, the detailed description of related art will be omitted from the description of the techniques disclosed herein. Further, the drawings are provided only for better understanding of the techniques disclosed herein, and the technical spirit should not be construed as limited thereto and thereby.

Description of Cables According to Embodiments Disclosed Herein

According to embodiments disclosed herein, a cable connects a first device with a second device, and the cable may include a power line that transfers power from the first device to the second device and a voltage compensator that compensates for a power receiving side voltage loss of the second device that is caused due to a voltage drop corresponding to the power line.

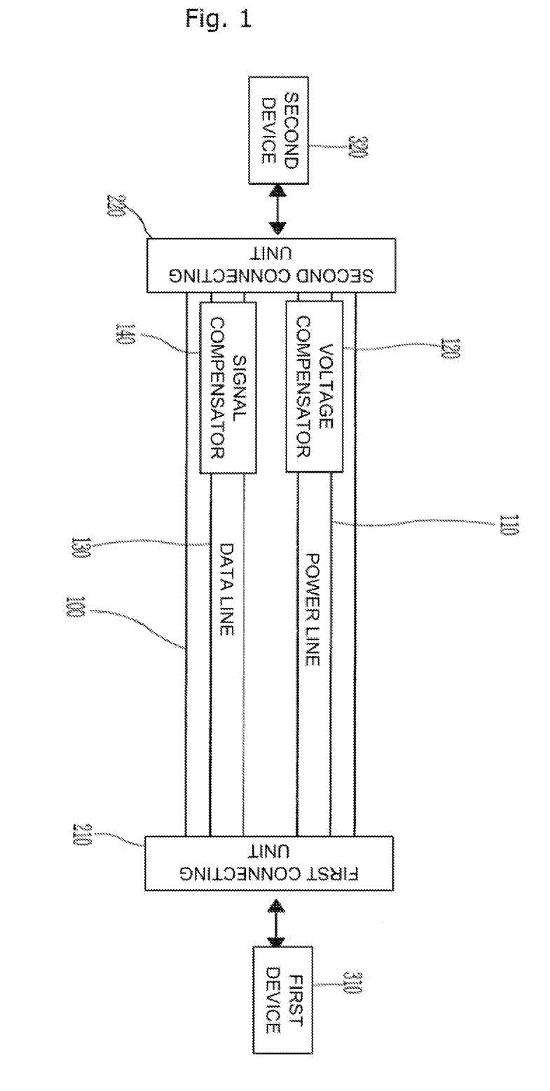

FIG. 1 is a block diagram illustrating a configuration of a cable according to embodiments disclosed herein.

Referring to FIG. 1, the cable 100) according to embodiments disclosed herein may include a power line 110 and a voltage compensator 120.

Further, the cable 100 according to an embodiment may further include a data line 130 and a signal compensator 140.

Further, the cable 100 according to an embodiment may further include a first connecting unit 210 and a second connecting unit 220.

Besides, the cable 100 may further include various components for high-speed transmission of signals and compensating for receiving-side voltage.

The components illustrated in FIG. 1 are not inevitable, but rather more or less components may be included in implementing the cable 100.

Hereinafter, the components are sequentially described.

The power line 110 is included in the cable connecting a first device 310 and a second device 320 with each other and may play a role to transfer power from the first device 310 to the second device 320.

The first device 310 may be a transmitting device for transmitting power to the second device 320. For example, the first device may be an HDTV (High-Definition Television), an IPTV (Internet Protocol Television), a terminal for digital broadcast, a 3D television, a DVD player, a set-top box, an A/V (Audio/Video) system, a home theater system or the like, which has a stable power supply source.

The second device 320 may be a portable device that may receive power from the first device 310 to recharge a battery. For example, the second device 320 may be a smartphone, a portable terminal, a mobile terminal, a personal digital assistant (PDA), a PMP (Portable Multimedia Player) terminal, a laptop computer, a Wibro terminal, a mobile phone, a tablet PC, or a digital camera.

The voltage compensator 120 may serve to compensate for a power receiving side voltage loss of the second device 320 that is caused due to a voltage drop corresponding to the power line 110.

In other words, a line current may flow through the power line 110 to transfer power from the first device 310 to the second device 320. Accordingly, the line current and a resistance component of the power line may cause a voltage drop to occur through the power line 110.

In such case, a difference in voltage may occur between a power source (or power) providing side (the first device 310) and a power source (or power) receiving side (the second device 320). That is, loss of the power receiving side voltage of the second device 320 may occur due to the voltage drop.

Since the specifications of the power source providing side (the second device 320) are in most cases determined so that its voltage is within a specific range, the cable being long may cause failure to meet the specifications due to the voltage drop by the resistance component and may thus serve as a factor limiting the maximum length of the cable. For example, the specifications may be determined so that the power receiving side voltage level of the second device 320 is permitted for a tolerance of ±10% from 5V, and in case the voltage drop in the power line 110 is 0.5V or more when the length of the cable is 1.5 m or more, the maximum length of the cable may be rendered to be limited to 1.5 m or less in applying a specific interface.

Accordingly, the voltage compensator 120 according to embodiments disclosed herein may function to compensate for the power receiving side voltage loss of the second device 320 that is caused due to the voltage drop to thereby increase the allowable maximum length.

The voltage compensator 120 may be disposed in various positions in the cable.

For example, the voltage compensator 120 may be disposed at the power transmitting side of the first device 310, the power receiving side of the second device 320, or the middle position of the power line 110.

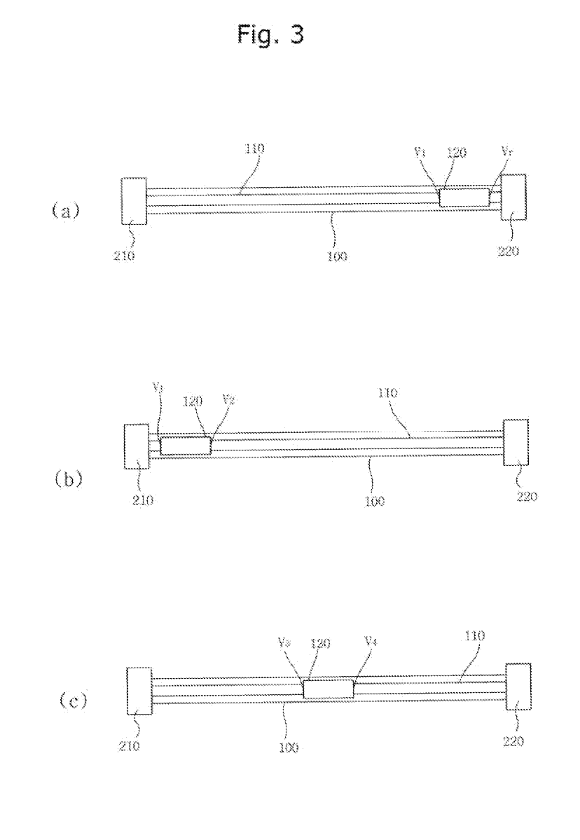

A method of disposing the voltage compensator 120 is described in detail below with reference to FIG. 3.

Further, the voltage compensator 120 may compensate for the power receiving side voltage loss by various methods.

For example, the voltage compensator 120 may compensate for the power receiving side voltage loss based on at least one of a line current flowing through the power line 110 and a power receiving side voltage of the second device 320.

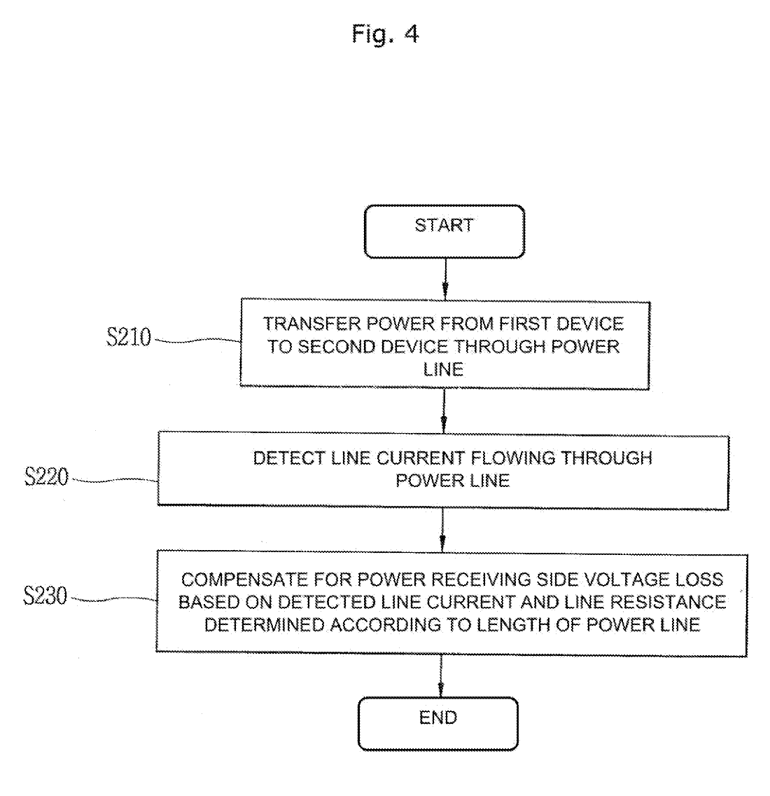

A method of compensating for the power receiving side voltage loss by the voltage compensator 120 is described in detail below with reference to FIGS. 4 to 8.

The data line 130 is included in the cable 100 and may play a role to transfer a data signal from the second device 320 to the first device 310. Here, the data signal may be a differential data signal.

The data line 130 may be manufactured (or configured) to have the same material or standard as the power line 110 or a different material or standard from the power line 110. For example, the data line 130 may be thinner than the power line 110.

The signal compensator 140 may function to compensate for the data signal loss that is caused due to signal transmission characteristics of the data line 130.

The signal compensator 140 may be configured to have various forms or structures. For example, the signal compensator 140 may be a boosting amplifier or an equalizer.

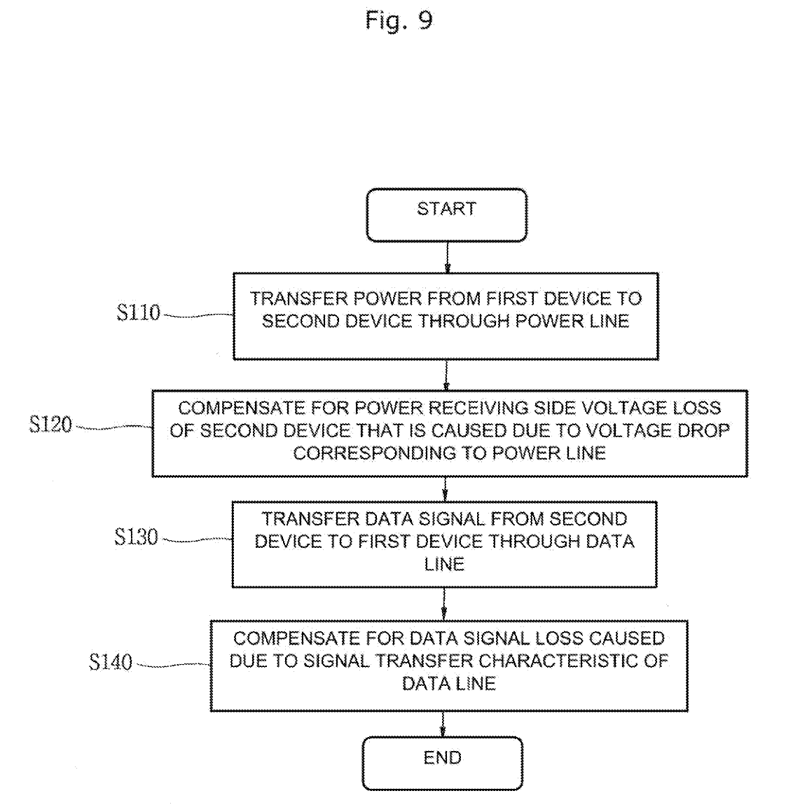

A method of compensating for the data signal loss by the signal compensator 140 is described below in detail with reference to FIG. 9 to 11b.

The first connecting unit 210 may play a role to connect the first device 310 with the cable 100. The first connecting unit 210 may include a pin (or port) for connection between the first device 310 and the cable 100), a simple electric circuit or an electronic circuit.

The second connecting unit 220 may play a role to connect the second device 320 with the cable 100. The second connecting unit 220 may include a pin (or port) for connection between the second device 320 and the cable 100, a simple electric circuit or an electronic circuit.

The first connecting unit 210 and the second connecting unit 220 may be interpreted with common terms used in the instant technical field. The first connecting unit 210 and the second connecting unit 220 may be connecting means that are commonly known and applicable in the instant technical field, and detailed description thereof is skipped.

Method of Compensating for Cable According to Embodiments Disclosed Herein

A compensation method of a cable according to embodiments disclosed herein may include the steps of transferring power from a first device through a power line to a second device and compensating for a power receiving side voltage loss of the second device that is caused due to a voltage drop corresponding to the power line.

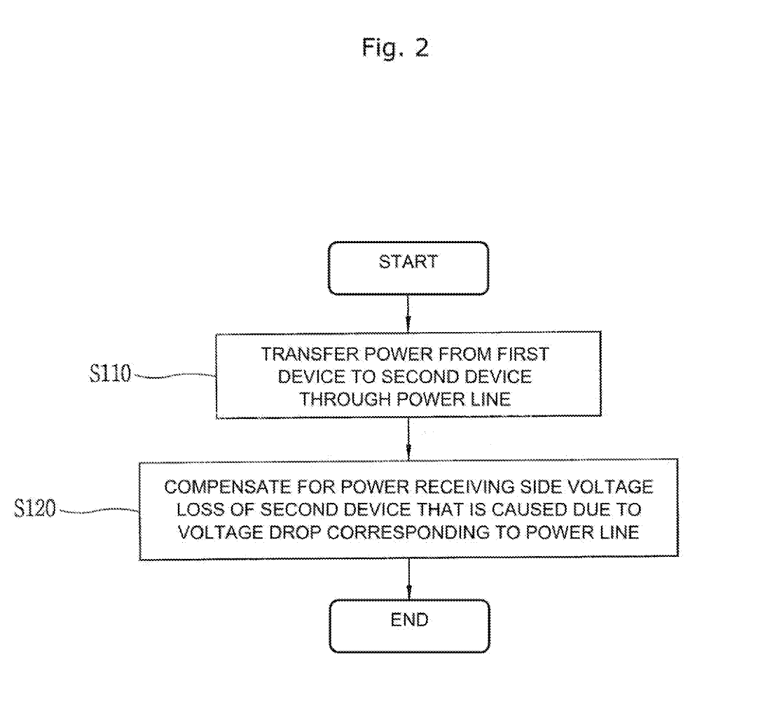

FIG. 2 is a flowchart illustrating a compensation method of a cable according to embodiments disclosed herein.

Referring to FIG. 2, the compensation method of the cable according to embodiments disclosed herein may include the following steps.

First, the compensation method of the cable according to embodiments disclosed herein may include the step of transferring power from a first device to a second device through a power line (S110).

Next, the compensation method of the cable according to embodiments disclosed herein may include the step of compensating for a power receiving side voltage loss of the second device that is caused due to a voltage drop corresponding to the power line (S120).

The compensation for the power receiving side voltage loss may be performed based on at least one of a line current flowing through the power line and a power receiving side voltage of the second device.

A specific method of compensating for the power receiving side voltage loss is described below in detail with reference to FIGS. 4 to 8.

Further the compensation method of the cable according to embodiments disclosed herein may further include the steps of transferring a data signal from the second device to the first device through the data line and compensating for a loss of the data signal that is caused due to signal transfer characteristics of the data line.

A specific method of compensating for the data signal loss is described below in detail with reference to FIGS. 9 to 11b.

First Embodiment-Arrangement of Voltage Compensator

The first embodiment disclosed herein may be implemented by some or combinations of the components or steps included in the above-described embodiments or combinations of the embodiments. Hereinafter, description of the duplicates will be skipped for clear expression of the first embodiment disclosed herein.

The cable according to the first embodiment disclosed herein may include a power line transferring power from a first device to a second device and a voltage compensator compensating for a power receiving side voltage loss of the second device that is caused due to a voltage drop corresponding to the power line.

Further, according to the first embodiment, the voltage compensator may be disposed at a power transmitting side of the first device, a power receiving side of the second device, or a middle position of the power line.

FIG. 3 is a view illustrating a method of disposing a voltage compensator according to the first embodiment disclosed herein.

Referring to FIG. 3, the voltage compensator 120 may be disposed at various positions on the power line of the cable.

As shown in FIG. 3(a), the voltage compensator 120 may be disposed at a power receiving side of the second device 320 (or positioned closer to the second device 320). In such case, the voltage compensator 120 may compensate for the power receiving side voltage loss of the second device 320 by adjusting an output voltage Vr of the voltage compensator 120 so that the output voltage Vr is equal to a voltage obtained by adding a voltage drop corresponding to the power line 110 to an input voltage V1 of the voltage compensator 120.

For example, in case the power transmitting side voltage of the first device 310 is 5V, and the voltage drop corresponding to the overall power line 110 is 0.5V, the input voltage V1 may be 4.5V. Accordingly, the voltage compensator 120 may compensate for the power receiving side voltage loss by adjusting the output voltage Vr to be the same as the voltage, 5V, obtained by adding the voltage drop, 0.5V, to the input voltage V1.

Further, as shown in FIG. 3(b), the voltage compensator 120 may be disposed at a power transmitting side of the first device 310 (or positioned closer to the first device 310). In such case, the voltage compensator 120 may compensate for the power receiving side voltage loss of the second device 320 by adjusting an output voltage V2 of the voltage compensator 120 so that the output voltage V2 is equal to a voltage obtained by adding a voltage drop corresponding to the power line 110 to an input voltage Vt of the voltage compensator 120.

For example, in case the power transmitting side voltage of the first device 310 is 5V, and the voltage drop corresponding to the overall power line 110 is 0.5V, the input voltage Vt may the same as the power transmitting side voltage, and thus, the input voltage Vt may be 5V. Accordingly, the voltage compensator 120 may compensate for the power receiving side voltage loss by adjusting the output voltage V2 to be the same as the voltage, 5.5V, obtained by adding the voltage drop, 0.5V, to the input voltage Vt.

Further, as shown in FIG. 3(c), the voltage compensator 120 may be disposed at a middle position of the power line 110. In such case, the voltage compensator 120 may compensate for the power receiving side voltage loss of the second device 320 by adjusting an output voltage V4 of the voltage compensator 120 so that the output voltage V4 of the voltage compensator 120 is equal to the voltage obtained by adding a voltage drop corresponding to the power line 110 to an input voltage V3 of the voltage compensator 120.

For example, in case the power transmitting side voltage of the first device 310 is 5V, and the voltage drop corresponding to the overall power line 110 is 0.5V, the input voltage V3 may be attenuated from the power transmitting side voltage by a voltage drop, 0.25V, corresponding to a half the length of the power line, and may thus be 4.75V. Accordingly, the voltage compensator 120 may compensate for the power receiving side voltage loss by adjusting the output voltage V4 to be equal to the voltage, 5.25V, obtained by adding the voltage drop, 0.5V, to the input voltage V3. In such case, the power receiving side voltage may be attenuated again from the output voltage V4 by the voltage drop, 0.25V, corresponding to a half the length of the power line, and may be thus 5V.

As described above, the voltage compensator 120 may be disposed at various positions on the power line 110, and the voltage compensator 120 may compensate for the power receiving side voltage loss by adjusting the output voltage of the voltage compensator 120 to be the same as the voltage obtained by adding the voltage drop corresponding to the overall power line 110 to the input voltage of the voltage compensator 120.

According to a variation of the first embodiment, in case the voltage compensator 120 is positioned at the power transmitting side, it may be included in the first connecting unit 210 when implementing the cable 100.

According to another variation of the first embodiment, in case the voltage compensator 120 is positioned at the power receiving side, it may be included in the second connecting unit 220 when implementing the cable 100.

Second Embodiment-Voltage Compensator Compensating for Voltage Loss that is Caused Due to Voltage Drop

The second embodiment disclosed herein may be implemented by some or combinations of the components or steps included in the above-described embodiments or combinations of the embodiments. Hereinafter, description of the duplicates will be skipped for clear expression of the second embodiment disclosed herein.

The cable according to the second embodiment disclosed herein may include a power line transferring power from a first device to a second device and a voltage compensator compensating for a power receiving side voltage loss of the second device that is caused due to a voltage drop corresponding to the power line.

Further, according to the second embodiment, the voltage compensator may compensate for the power receiving side voltage loss in various ways. For example, the voltage compensator may compensate for the power receiving side voltage loss based on at least one of a line current flowing through the power line and a voltage at the power receiving side of the second device.

For example, in case the voltage compensator compensates for the power receiving side voltage loss based on the power receiving side voltage of the second device, the voltage compensator may include a voltage detector (not shown) for detecting the power receiving side voltage, and in case the power receiving side voltage detected by the voltage detector does not reach a predetermined standard voltage (for example, 5V±0.5V) due to a voltage drop corresponding to the power line, the voltage compensator may compensate for the power receiving side voltage loss by adjusting the output voltage of the voltage compensator to be the same as the voltage obtained by adding the standard voltage and a difference between the power receiving side voltages to the input voltage of the voltage compensator.

Besides, it is apparent to one of ordinary skill in the art that the power receiving side voltage loss may be compensated by other various methods.

A method of compensating for the power receiving side voltage loss based on a line current flowing through the power line is now described below in detail.

According to a second embodiment, the voltage compensator may compensate for the power receiving side voltage loss based on a line resistance determined according to the length of the power line and the detected line current.

Further, according to the second embodiment, the voltage compensator may compensate for the power receiving side voltage loss by detecting a voltage drop by multiplying the detected line current with the line resistance and adjusting the output voltage of the voltage compensator to be the same as the voltage obtained by adding the detected voltage drop to the input voltage of the voltage compensator.

Further, according to a variation of the second embodiment, the voltage compensator may compensate for the power receiving side voltage loss by detecting a voltage drop by multiplying the detected line current with the line resistance, detecting a reference voltage by adding the detected voltage drop and a target voltage, and adjusting the output voltage of the voltage compensator to be the same as the reference voltage. Here, the target voltage may be a power receiving side voltage of the second device that is to be obtained through voltage compensation by the voltage compensator.

FIG. 4 is a flowchart illustrating a compensation method of a cable according to the second embodiment disclosed herein.

Referring to FIG. 4, the compensation method of the cable according to the second embodiment disclosed herein may include the following steps.

First, the compensation method of the cable according to the second embodiment disclosed herein may transfer power from a first device to a second device through a power line (S210).

Next, the compensation method of the cable according to the second embodiment disclosed herein may detect a line current flowing through the power line (S220).

Then, the compensation method of the cable according to the second embodiment disclosed herein may compensate for the power receiving side voltage loss based on the detected line current and a line resistance determined according to the length of the power line (S230).

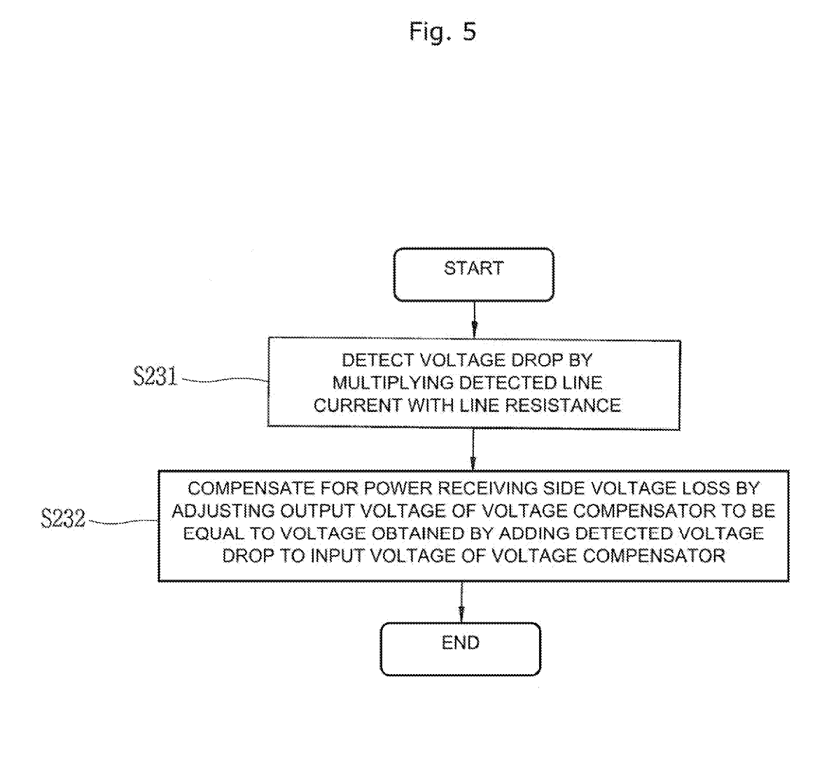

FIG. 5 is a flowchart illustrating a method of compensating for a voltage based on a detected line current and a line resistance according to the second embodiment disclosed herein.

Referring to FIG. 5, the method of compensating for the voltage based on the detected line current and line resistance according to the second embodiment disclosed herein may include the following steps.

First, the method of compensating for the voltage based on the line current and the line resistance may include the step of detecting a voltage drop by multiplying the detected line current with the line resistance (S231).

Next, the method of compensating for the voltage based on the detected line current and line resistance may include the step of compensating for the power receiving side voltage loss by adjusting the output voltage of the voltage compensator to be the same as the voltage obtained by adding the detected voltage drop to the input voltage of the voltage compensator (S232).

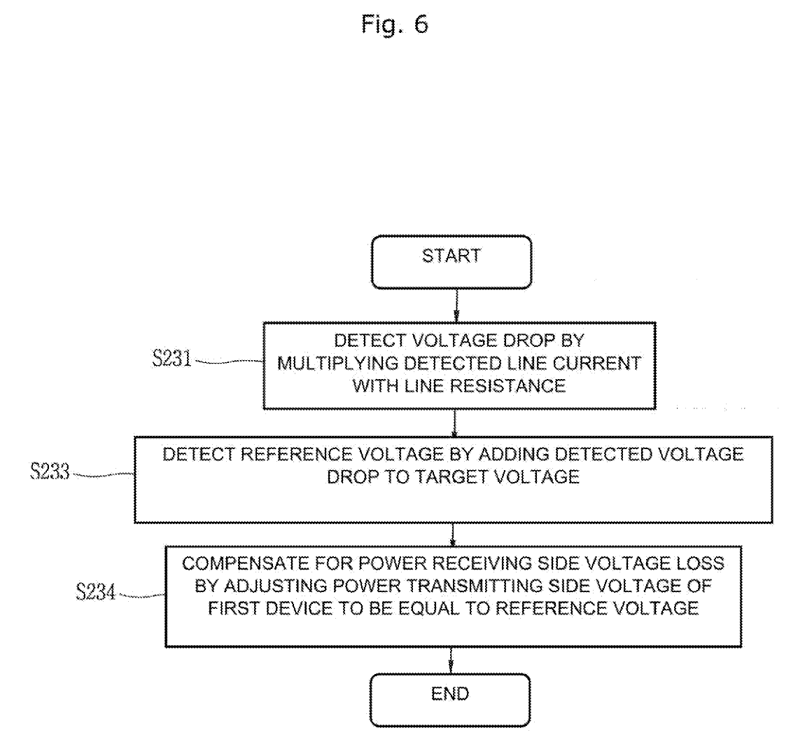

FIG. 6 is a flowchart illustrating a method of compensating for a voltage based on a detected line current and a line resistance according to another second embodiment disclosed herein.

Referring to FIG. 6, the method of compensating for the voltage based on the detected line current and line resistance according to the other second embodiment disclosed herein may include the following steps.

First, the method of compensating for the voltage based on the line current and the line resistance may include the step of detecting a voltage drop by multiplying the detected line current with the line resistance (S231).

Next, the method of compensating for the voltage based on the detected line current and the line resistance may include the step of detecting a reference voltage by adding the detected voltage drop and a target voltage (S233).

Then, the method of compensating for the voltage based on the detected line current and the line resistance may include the step of compensating for the power receiving side voltage loss by adjusting the power transmitting side voltage of the first device to be the same as the reference voltage (S234).

Here, the target voltage may be a power receiving side voltage of the second device that is to be obtained through voltage compensation by the voltage compensator.

According to the second embodiment, the voltage compensator may need to be aware of the line current and line resistance of the power line so as to compensate for the power receiving side voltage loss.

That is, since the magnitude of the voltage drop varies depending on the length (or the line resistance) of the cable (or power line) and the magnitude of a line current supplied, the amount of voltage compensated by the voltage compensator should be able to be adjusted to fit for the length of the cable and the magnitude of the current. Since the length of the cable is fixed at the assembling step, its resistance as per length may be predicted at the assembling step. However, since the magnitude of current supplied is determined when using an actual cable in a communication system (or interface system), it may not be predicted at the assembling step. Accordingly, the magnitude of current may need to be measured by a circuit.

Accordingly, the voltage compensator according to the second embodiment may further include a current detector to detect a line current flowing through the power line. The current detector may be implemented in various forms or structures. The current detector may be interpreted with common terms used in the instant technical field. The current detector may be a current detecting means that is commonly known and applicable in the instant technical field, and detailed description thereof is skipped.

Further, the voltage compensator may need to include a resistor corresponding to the line resistance or store the line resistance in order to compensate for the receiving side voltage loss using the line resistance.

According to the second embodiment, the voltage compensator may further include a resistor corresponding to the line resistance, and the voltage drop may be a voltage generated between both ends of the resistor based on the line current flowing through the resistor. In such case, the voltage compensator may enable the detected line current to flow through the resistor corresponding to the line resistance and may detect the voltage drop based on the voltage between both ends of the resistor.

According to another second embodiment, the voltage compensator may further include a memory for storing the line resistance. For example, the memory may be an OTP (One Time Programmable Memory). Further, for example, the memory may store line resistances according to the length of the power line in the form of a table. In such case, the voltage compensator may detect the length of the cable, obtain a line resistance corresponding to the length of the cable from the table stored in the memory, and use the obtained line resistance for compensating for the power receiving side voltage loss.

According to the second embodiment, the voltage compensator may be implemented in various forms or structures. The voltage compensator may include a DC-DC (DC to DC converter) or a boost converter. Besides, it is apparent to one of ordinary skill in the art that various types of voltage compensators may be applicable to the method of compensating for the voltage as disclosed herein.

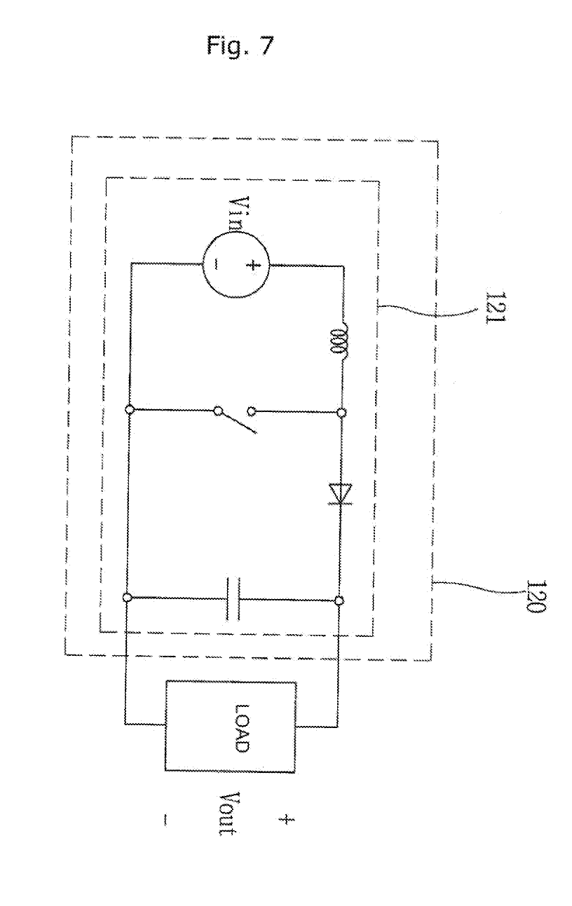

FIG. 7 is a view illustrating an example structure of a voltage compensator according to the second embodiment disclosed herein.

Referring to FIG. 7, the voltage compensator 120 may include a DC-DC converter that compensates for a voltage drop that occurs from the power line 110.

FIG. 7 illustrates an example in which the voltage compensator 120 includes a boost converter 121 as a DC-DC converter.

In such case, the boost converter 121 may operate so that the output voltage Vout is equal to the voltage obtained by adding a particular voltage to the input voltage Vin.

Here, the input voltage Vin may be a voltage transferred from the power transmitting side of the first device to the boost converter 121, and the output voltage Vout may be a voltage that has been subjected to compensation for a voltage loss that is caused due to a voltage drop corresponding to the power line 110. The output voltage Vout may be transferred again to the power receiving side of the second device.

The particular voltage may be determined according to various criteria. For example, the particular voltage may be determined so that the power receiving side voltage of the second device is a voltage intended to be obtained through compensation for the power receiving side voltage loss. Further, for example, the particular voltage may be a voltage drop corresponding to the power line 110.

The operation of the voltage compensator 120 for compensating for a voltage loss according to the second embodiment in case the particular voltage is the voltage drop is specifically described below. First, the voltage compensator 120 may detect a line current flowing through the power line 110. To the end, the voltage compensator 120 may include a current detecting means (or current detector not shown) for detecting the line current.

Next, the voltage compensator 120 may detect a voltage drop by multiplying the line resistance with the detected line current.

Then, the voltage compensator 120 may compensate for the power receiving side voltage loss by adjusting the output voltage Vout of the voltage compensator 120 to be equal to the voltage obtained by adding the detected voltage drop to the input voltage Vin of the voltage compensator 120. Here, the operation (or boosting operation) of adding the voltage drop to the input voltage Vin may be conducted by the boost converter 121. The control to enable the output voltage Vout to be equal to the voltage obtained by adding the particular voltage to the input voltage Vin may be done by controlling a switch included in the boost converter 121.

The operation of the boost converter 121 is the technique commonly known in the instant technical field, and detailed description thereof is skipped.

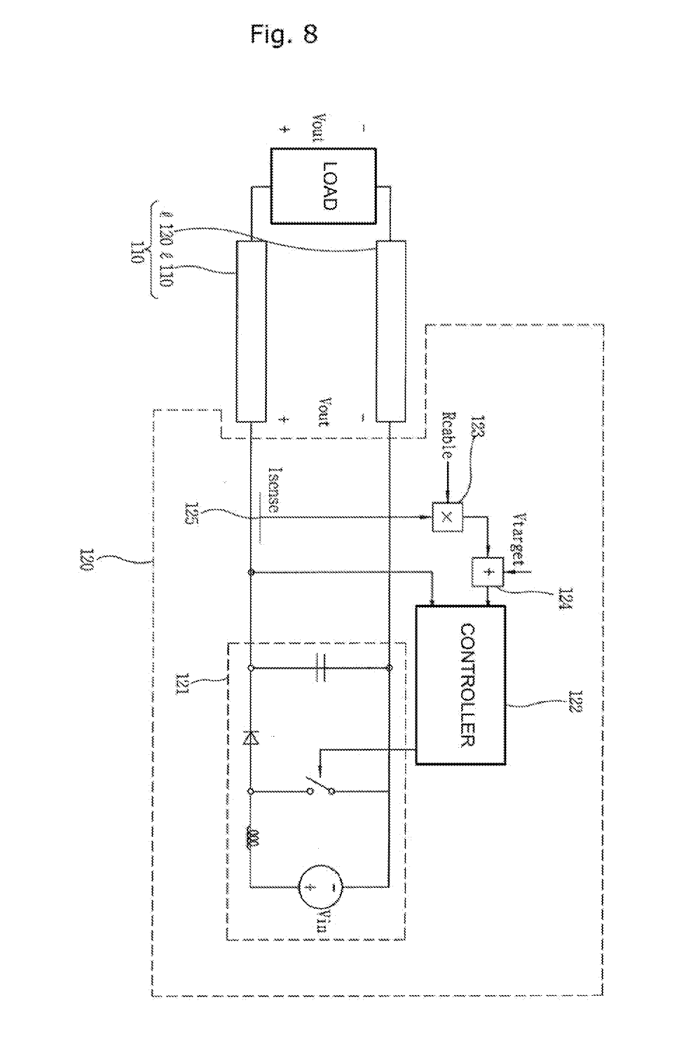

FIG. 8 is a view illustrating an example structure of a voltage compensator according to still another second embodiment disclosed herein.

Referring to FIG. 8, the voltage compensator 120 according to the second embodiment may include a boost converter 121, a controller 122, a multiplier 123, an adder 124, and a current detector 125. The boost converter 121, the controller 122, the multiplier 123, the adder 124, and the current detector 125 may be implemented in various forms or structures.

As an example, the multiplier 123, as described above, may include a resistor corresponding to a line resistance corresponding to the power line 110. In such case, the voltage drop corresponding to the power line 110 may be a voltage generated between both ends of the resistor based on the line current flowing through the resistor.

The above components 121, 122, 123, 124, and 125, when implemented, may adopt the forms or structures commonly known in the technical field, and detailed description thereof is thus skipped.

Further, FIG. 8 illustrates an example in which the voltage compensator 120 is disposed at the power transmitting side of the first device 310. Accordingly, the output voltage Vout′ of the voltage compensator 120 may be applied to a power source line 1110 and a ground (or earth) line 1120 constituting the power line 110. At this time, the output voltage Vout′ goes through voltage drop via the power line 110 to be a load voltage Vout.

The operation of the voltage compensator 120 according to the second embodiment is specifically described with reference to FIG. 8. The current detector 125 may detect (or sense) a line current Isense flowing through the power line 110 and may transfer the detected line current Isense to the multiplier 123.

The multiplier 123 may detect a voltage drop by multiplying the detected line current with a line resistance Rcable corresponding to the power line and may transfer the voltage drop value to the adder 124.

The adder 124 may add a target voltage Vtarget to the voltage drop value to thereby detect a reference voltage and may transfer the reference voltage value to the controller 122. Here, the target voltage Vtarget may be a power receiving side voltage (or load voltage Vout) of the second device, which intends to be obtained through voltage compensation of the voltage compensator.

For example, in case the power transmitting side voltage (or input voltage Vin) of the first device is 4.75V that is lower than a rated (or standard) voltage, 5V, and a voltage drop value corresponding to the power line 110 is 0.5V, the target voltage, although the power transmitting side voltage is 4.75V, may be the rated voltage, 5V. That is, in this case, the target voltage Vtarget may be an ideal voltage (target voltage or rated voltage) that should be received by the power receiving side.

The controller 122 may control the boost converter 121 so that the output voltage Vout′ is equal to the reference voltage value (Vtarget+Isense×Rcable) in addition to the input voltage Vin (for example, by controlling a switch included in the boost converter 121).

Third Embodiment-Signal Compensator Compensating for Data Signal Loss

The third embodiment disclosed herein may be implemented by some or combinations of the components or steps included in the above-described embodiments or combinations of the embodiments. Hereinafter, description of the duplicates will be skipped for clear expression of the third embodiment disclosed herein.

The cable according to the third embodiment disclosed herein may include a power line transferring power from a first device to a second device and a voltage compensator compensating for a power receiving side voltage loss of the second device that is caused due to a voltage drop corresponding to the power line.

Further, the cable according to the third embodiment may further a data line transferring a data signal from the second device to the first device and a signal compensator that compensates for the data signal loss generated due to signal transfer characteristics of the data line.

FIG. 9 is a flowchart illustrating a compensation method of a cable according to the third embodiment disclosed herein.

Referring to FIG. 9, the compensation method of the cable according to the third embodiment disclosed herein may include the following steps.

First, the compensation method of the cable according to the third embodiment disclosed herein may include the step of transferring power from the first device to the second device through a power line (S110).

Next, the compensation method of the cable according to the third embodiment disclosed herein may include the step of compensating for a power receiving side voltage loss of the second device that is caused due to a voltage drop corresponding to the power line (S120).

Thereafter, the compensation method of the cable according to the third embodiment disclosed herein may include the step of transferring a data signal from the second device to the first device through the data line (S130).

Then, the compensation method of the cable according to the third embodiment disclosed herein may include the step of compensating for a data signal loss that is caused due to the signal transfer characteristics of the data line (S140).

The cable according to the third embodiment may include the data line for transferring a data signal from the second device to the first device.

Accordingly, the cable according to the third embodiment may include the signal compensator for compensating for the data signal loss that is caused due to the signal transfer characteristics of the data line in addition to the voltage compensator for compensating for the power receiving side voltage loss that is caused due to a voltage drop corresponding to the power line.

The signal compensator may be implemented in various forms or structures. For example, the signal compensator may include various types of equalizers. In case the signal compensator is implemented as an equalizer, a circuit may be most commonly used that has high-pass frequency characteristics so as to be able to compensate for the low-pass frequency characteristics of the cable.

For example, the signal compensator may include a boosting amplifier that is an analog equalizer. Further, for example, the signal compensator may include a DFE (Decision Feedback Equalization) that is a digital filter-type equalizer. Besides, it is apparent to one of ordinary skill in the art that the signal compensator may be implemented in various forms or structures.

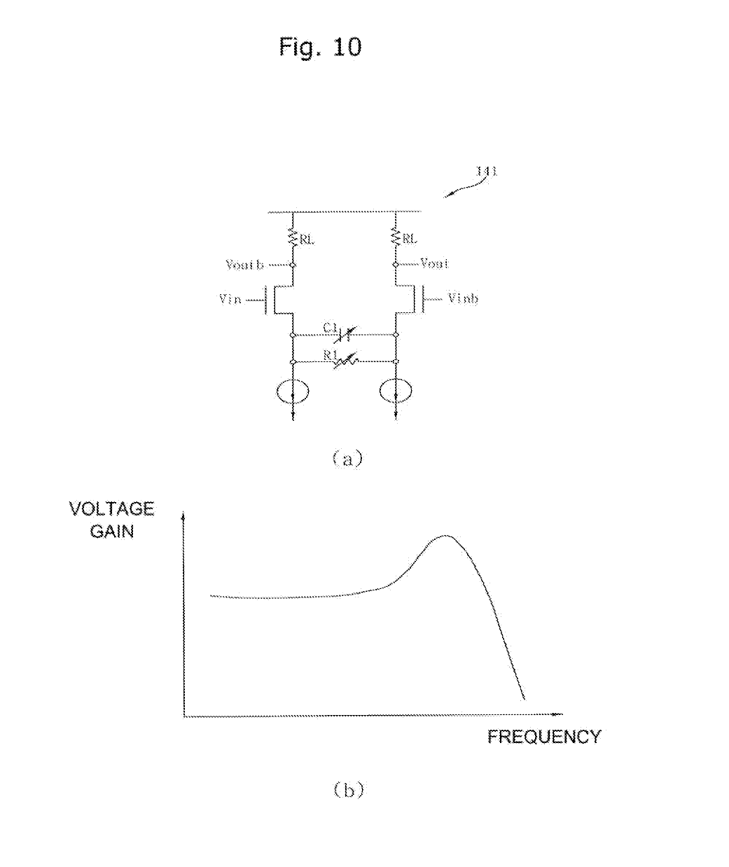

FIG. 10 is a view illustrating an example signal compensator according to the third embodiment disclosed herein.

FIG. 10(a) shows an example in which the signal compensator includes a boosting amplifier 141 and data transmitted from the second device is differential signals.

The boosting amplifier 141 may receive differential signals Vin and Vinb and may output signals with emphasized high-frequency components. The operation of the boosting amplifier 141 is commonly well known in the instant technical field, and thus, detailed description thereof is skipped.

FIG. 10(b) illustrates a per-frequency voltage gain characteristic (or frequency characteristic) of the signal compensator.

As shown in FIG. 10(b), the signal compensator may have the frequency characteristic of having an emphasized (or amplified) specific frequency band in order to compensate for a high frequency band loss that is caused due to the signal transfer characteristics of the data line.

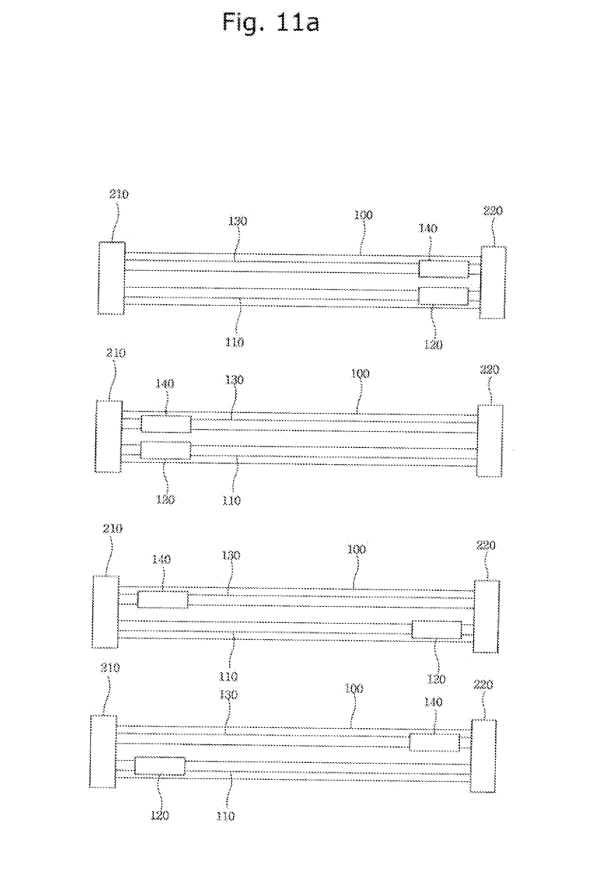

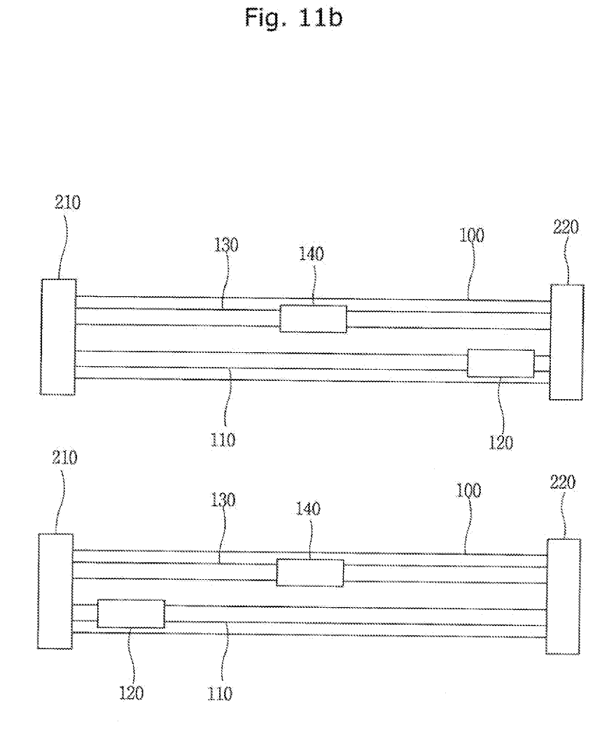

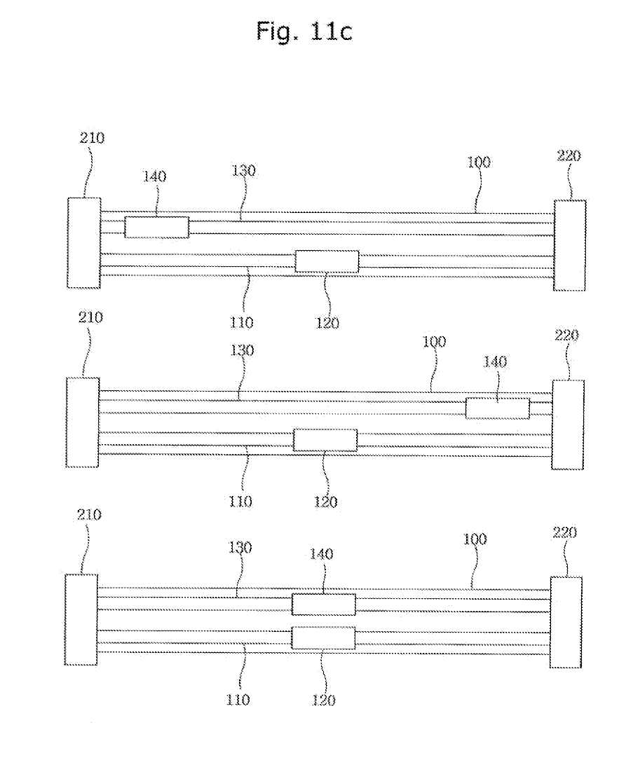

FIGS. 11a to 11c are views illustrating example arrangements of a voltage compensator and a signal compensator according to the third embodiment disclosed herein.

Referring to FIGS. 11a to 11c, the voltage compensator 120 may be disposed at a power transmitting side of the first device, a power receiving side of the second device, or a middle position of the power line on the power line 110 included in the cable 100.

Further, the signal compensator 14 may be disposed at a data receiving side of the first device, a data transmitting side of the second device, or a middle position of the data line on the data line 130 included in the cable 100.

Accordingly, as shown in FIGS. 11a to 11c, according to arrangement combinations, there may be nine arrangements of the voltage compensator 120 and the signal compensator 140 that may be included in the cable 100.

Applicable Field of Techniques Disclosed Herein

The cable and compensation method of the cable according to the embodiments disclosed herein may be applicable to various fields as described above.

For example, the cable disclosed herein may be applicable to the technical fields of protocols or interfaces relating to wired communications. Specifically, the cable may be applicable to the technical fields of USB (Universal Serial Bus) ports, HDMI (High-Definition Multimedia Interface) ports, DPs (Display Ports), MHLs (Mobile High-Definition Links), wired/wireless headset ports, external recharger ports, wired/wireless data ports, memory card ports, ports for connection of identification module-equipped devices. Audio I/O (Input/Output) ports, video I/O (Input/Output) ports, or earphone ports.

An example of applying the cable to an MHL (Mobile High-Definition Link) that is a next-generation interface is now described below in detail.

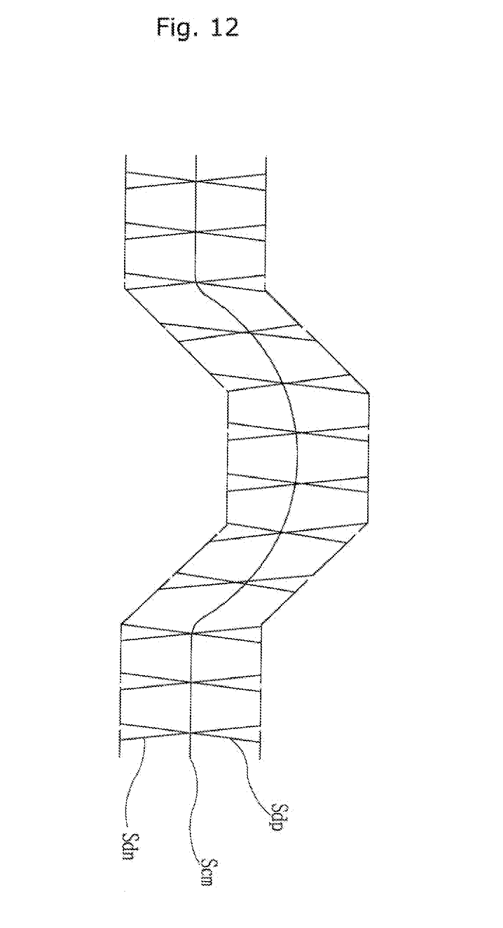

FIG. 12 is a view illustrating example waveforms of signals from an MHL system.

Referring to FIG. 12, the MHL (Mobile High Definition Link) may transmit data through a pair of differential signals Sdp and Sdn and may modulate the common-mode level (Scm) of the differential signals to transmit a clock signal.

The signal compensator 140 may compensate for signal attenuation of the differential signals Sdp and Sdn due to the signal transfer characteristics of the data line 130. For example, the compensation of the signal attenuation of the differential signals Sdp and Sdn may be performed by the boosting amplifier 141.

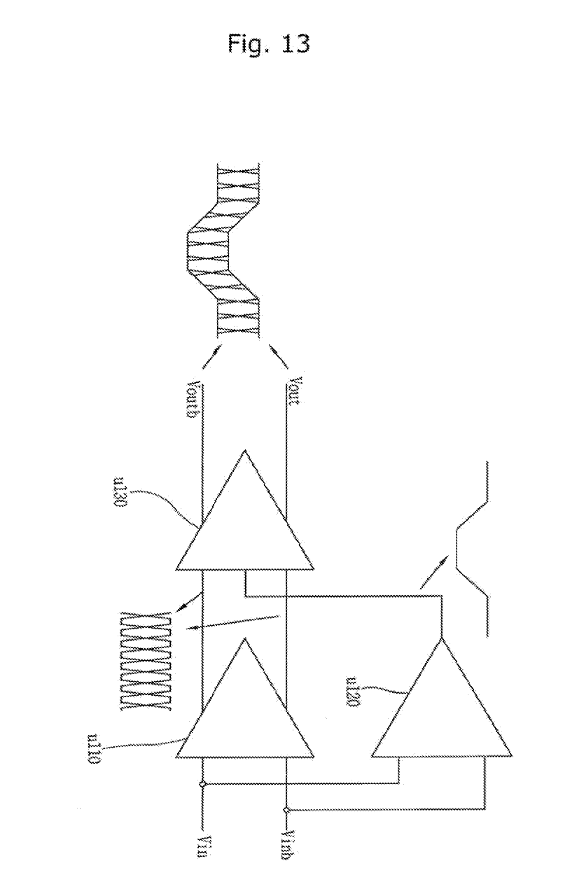

FIG. 13 is a concept view illustrating a method of compensate for a signal in an MHL system.

Referring to FIG. 13, the boosting amplifier 141 may basically amplify differential signals while cutting off (rejecting) common-mode signals. Accordingly, in case the signal attenuation of MHL signals (or differential signals) is compensated through the boosting amplifier 141, a modulated component of a common-mode level (Scm) indicating a clock signal is mostly attenuated and thus does not appear in the outputs Vout and Voutb. Accordingly, in the case of an MHL signal, signal attenuation of differential signals that are data components may be compensated through an equalizer u110, and the common-mode level Scm may be restored by a separate circuit (CM level extractor, u120).

Thereafter, a signal combiner u130 may combine the restored common-mode level Scm with the outputs from the boosting amplifier 141 to generate an MHL signal.

Of course, if the boosting amplifier 141 or any other circuit may perform both compensation for attenuated differential signals Sdp and Sdn and treatment of modulated components of the common-mode level Scm, the single circuit may be implemented to conduct all of the operations.

Further, the MHL cable may include a power line that may transfer power from the first device to the second device.

MHL is a standard for portable audio/video interfaces that enables a mobile terminal or other portable electronic device (for example, portable consumer electronics (CE)) to be directly connected to an HDTV (High-Definition Television) or other display device, and thus, the first device may be an HDTV (High-Definition Television) or other display apparatus while the second device may be a mobile terminal or other portable electronic device (for example, portable consumer electronics (CE)).

Therefore, according to the techniques disclosed herein, the MHL cable may include a voltage compensator (e.g., a DC-DC converter) for compensating for a voltage drop that is caused due to a resistance component of the power line included in the MHL cable.

As described above, the voltage compensator may serve to compensate for a power receiving side voltage loss of the second device that is caused due to a voltage drop corresponding to the power line.

The scope of the present invention is not limited to the embodiments disclosed herein, and various changes, modifications, and variations may be made thereto without departing from the spirit and scope of the present invention as defined in the following claims.

1. A cable connecting a first device and a second device with each other, the cable comprising:
a power line transferring power from the first device to the second device; and
a voltage compensator compensating for a power receiving side voltage loss of the second device that is caused due to a voltage drop corresponding to the power line.

2. The cable of claim 1, wherein the voltage compensator includes a DC-DC (DC to DC) converter or a boost converter.

3. The cable of claim 1, wherein the voltage compensator compensates for the power receiving side voltage loss based on at least one of a line current flowing through the power line and a power receiving side voltage of the second device.

4. The cable of claim 1, further comprising a current detector detecting a line current flowing through the power line.

5. The cable of claim 4, wherein the voltage compensator compensates for the power receiving side voltage loss based on the detected line current and a line resistance determined depending on a length of the power line.

6. The cable of claim 5, wherein the voltage compensator detects a voltage drop by multiplying the detected line current with the line resistance and adjusts an output voltage of the voltage compensator to be the same as a voltage obtained by adding the detected voltage drop to an input voltage of the voltage compensator to thus compensate for the power receiving side voltage loss.

7. The cable of claim 6, wherein the voltage compensator further includes a resistor corresponding to the line resistance, and wherein the voltage drop is a voltage that is generated between both ends of the resistor based on the line current flowing through the resistor.

8. The cable of claim 5, further comprising a memory storing the line resistance.

9. The cable of claim 8, wherein the memory is an OTP (One Time Programmable Memory).

10. The cable of claim 8, wherein the memory stores the line resistance according to a length of the power line in the form of a table.

11. The cable of claim 5, wherein the voltage compensator detects a voltage drop by multiplying the detected line current with the line resistance, detects a reference voltage by adding the detected voltage drop to a target voltage, and adjusts an output voltage of the voltage compensator to be the same as the reference voltage to thus compensate for the power receiving side voltage loss.

12. The cable of claim 11, wherein the target voltage is a power receiving side voltage of the second device that is to be obtained through voltage compensation by the voltage compensator.

13. The cable of claim 1, wherein the voltage compensator is disposed at a power transmitting side of the first device, a power receiving side of the second device, or a middle position of the power line.

14. The cable of claim 1, further comprising:
a data line transferring a data signal from the second device to the first device; and
a signal compensator compensating for a loss of the data signal that is caused due to a signal transfer characteristic of the data line.

15. The cable of claim 14, wherein the signal compensator includes a boosting amplifier or a DFE (Decision Feedback Equalization).

16. The cable of claim 14, wherein the signal compensator is disposed at a data receiving side of the first device, a data transmitting side of the second device, or a middle position of the data line.

17. The cable of claim 14, wherein the voltage compensator obtains information on a voltage drop corresponding to the power line from the signal compensator and compensates for the power receiving side voltage loss based on the obtained information on the voltage drop.

18. The cable of claim 14, wherein the data signal is a differential data signal.

19. A compensation method of a cable, the compensation method comprising the steps of:
transferring power from a first device to a second device through a power line;
detecting a line current flowing through the power line; and
compensating for a power receiving side voltage loss of the second device based on the detected line current and a line resistance determined depending on a length of the power line.

20. The compensation method of claim 19, wherein the step of compensating for the power receiving side voltage loss comprises the steps of:
detecting a voltage drop by multiplying the detected line current with the line resistance;
detecting a reference voltage by adding the detected voltage drop to a target voltage; and
adjusting a power transmitting side voltage of the first device to be the same as the reference voltage to compensate for the power receiving side voltage loss.

21. The compensation method of claim 19, further comprising the steps:
transferring a data signal from the second device to the first device through a data line; and
compensating for a loss of the data signal that is caused due to a signal transfer characteristic of the data line.
